(19) United States
(12) Patent Application Publication
(10) Pub. No.: US 2017/0159173 A9
(43) Pub. Date: Jun. 8, 2017

(54) FUNCTIONAL FILM MANUFACTURING METHOD AND FUNCTIONAL FILM

(71) Applicant: FUJIFILM Corporation, Tokyo (JP)

(72) Inventor: Eijiro IWASE, Kanagawa (JP)

(73) Assignee: FUJIFILM CORPORATION, Tokyo (JP)

(21) Appl. No.: 14/458,883

(22) Filed: Aug. 13, 2014

Related U.S. Application Data
(63) Continuation of application No. PCT/JP2012/082307, filed on Dec. 13, 2012.

(30) Foreign Application Priority Data
Feb. 15, 2012 (JP) 2012-030646

(51) Int. Cl. C23C 16/34; B05D 1/38; C23C 16/513

(52) U.S. Cl. CPC C23C 16/345; C23C 16/513; B05D 1/38

(57) ABSTRACT

An organic layer not containing halogen is formed on a substrate using a coating material, and a silicon nitride layer is formed on the organic layer by plasma CVD. Owing to the configuration, there is provided a functional film manufacturing method capable of stably manufacturing a high-performance functional film such as a gas barrier film having excellent gas barrier properties, as well as a functional film.

### CROSS-REFERENCE TO RELATED APPLICATIONS

This application is a Continuation of PCT International Application No. PCT/JP2012/082307 filed on Dec. 13, 2012, which claims priority under 35 U.S.C. §119(a) to Japanese Application No. 2012-030646 filed on Feb. 15, 2012. Each of the above application(s) is hereby expressly incorporated by reference, in its entirety, into the present application.

### BACKGROUND OF THE INVENTION

The present invention relates to a manufacturing method of an organic/inorganic laminate-type functional film obtained by forming an organic layer and a silicon nitride layer on a substrate, and a functional film.

In various apparatuses including optical apparatuses, display apparatuses such as liquid crystal displays or organic EL displays, various semiconductor apparatuses, and solar cells, a gas barrier film is used for portions or components that need to exhibit moisture-proof properties. The gas barrier film is also used as a material for packing foods, electronic parts, or the like.

The gas barrier film generally has the structure in which a plastic film such as a polyethylene terephthalate (PET) film is used as a substrate (support), and a film exhibiting gas barrier properties is formed on the substrate.

Regarding the structure that enables such a gas barrier film to exhibit a higher degree of gas barrier properties, an organic/inorganic laminate-type gas barrier film which has an organic layer as a base layer (undercoat layer) formed of an organic compound on a surface of a substrate and an inorganic layer formed of an inorganic compound exhibiting gas barrier properties on the organic layer, is known.

It is also known that when a film has plural laminate structures each consisting of an organic layer and an inorganic layer, a higher degree of gas barrier properties are obtained.

For example, JP 2009-262490 A discloses a gas barrier film having a gas barrier layer consisting essentially of an organic layer and an inorganic oxide layer, in which the organic layer in contact with the inorganic oxide layer contains a compound having silicon atoms or fluorine atoms, the thickness of the organic layer is 10 nm to 1 μm, and the thickness of the inorganic oxide layer is 5 nm to 500 nm.

Moreover, JP 2011-46060 A discloses a gas barrier film having an organic layer that consists of a first organic layer formed under the atmospheric pressure and a second organic layer formed in a vacuum, and an inorganic layer that is formed on the organic layer.

A surface of a plastic film used as a substrate (support) of the gas barrier film is not necessarily flat and has many fine irregularities. Furthermore, foreign substances such as dust adhere to the surface of the plastic film.

At the substrate having such irregularities or foreign substances, due to these irregularities, there are portions that cannot be covered with the inorganic layer, that is, portions to be “shadow,” so to speak. Pores (defect) are formed in the inorganic layer in the places that are not covered with the inorganic film on the substrate, and moisture is allowed to pass through the film.

Therefore, as described in JP 2009-262490 A and JP 2011-46060 A, in the organic/inorganic laminate-type gas barrier film, a surface on which the inorganic layer is to be formed is flattened by the organic layer formed on the substrate, so as to eliminate the “shadow” portions caused by the irregularities, that is, the portions that cannot be covered with (are not easily covered with) the inorganic layer.

In other words, the performance of the organic/inorganic laminate-type gas barrier film greatly depends on how much the organic layer, which is to be an underlayer of the inorganic layer, can eliminate various irregularities.

In JP 2009-262490 A, from the viewpoint of the covering properties, the organic layer contains a compound having silicon atoms or fluorine atoms. When the organic layer contains such a compound (for example, a surfactant), at the time of forming the organic layer, surface tension of a coating material that is to be the organic layer is reduced, and accordingly, surface smoothness of the organic layer surface on which the inorganic layer is to be formed is improved.

### SUMMARY OF THE INVENTION

In the meantime, as described in JP 2009-262490 A and JP 2011-46060 A, as the inorganic layer used for a gas barrier film, for example, layers (films) formed of various inorganic compounds such as silicon nitride, silicon oxide, and aluminum oxide are known.

Among these, a silicon nitride layer is known as an inorganic layer which makes it possible to obtain a high degree of gas barrier properties and can be formed into a film by plasma CVD, thus leading to excellent productivity.

As described above, the gas barrier film obtained by forming an organic layer on a substrate and forming a silicon nitride layer on the organic layer makes it possible to obtain a high degree of gas barrier properties.

The present inventor made a study and found that a gas barrier film obtained by forming a silicon nitride layer on an organic layer can stably exhibit intended gas barrier properties to the extent that the water vapor permeability is higher than 1×10⁻³ [g/(m²·day)]. However, in the case where a gas barrier film is manufactured with the intention of obtaining gas barrier properties of higher level than the above, intended gas barrier properties often cannot be obtained under certain conditions of the manufacturing method, the composition of the organic layer, and the like.

The present invention has been made to solve the problems of the conventional technologies, and an object thereof is to provide a functional film manufacturing method that makes it possible to stably achieve intended high performance of a functional film, such as a gas barrier film, which has an organic layer as an underlayer on a substrate and a silicon nitride layer exhibiting intended functions such as gas barrier properties on the organic layer. Another object of the present invention is to provide a functional film manufactured by the functional film manufacturing method.

In order to solve the foregoing problems, the present invention provides a functional film manufacturing method, comprising the steps of: forming an organic layer not containing halogen on a substrate by using a coating material; and forming a silicon nitride layer on the organic layer by plasma CVD.

In the functional film manufacturing method of the invention, preferably, the organic layer is formed of a coating material containing an organic solvent, an organic compound, and a surfactant, and the coating material contains the surfactant in an amount of 0.01% by weight to 10% by weight in terms of the concentration when the organic solvent is excluded.

Preferably, the organic layer is formed to have a thickness of 0.5 μm to 5 μm.

Preferably, the coating material is applied in an amount of 5 cc/m² to 50 cc/m² to form the organic layer.

Preferably, the substrate is drawn from a substrate roll obtained by taking up the substrate having a long length in a roll shape, the organic layer is formed by coating the substrate with the coating material, drying the coating material and curing an organic compound while the substrate is transported in a longitudinal direction, and the substrate on which the organic layer has been formed is taken up again in a roll shape to obtain a substrate/organic layer roll; and the substrate on which the organic layer has been formed is drawn from the substrate/organic layer roll, the silicon nitride layer is formed while the substrate is transported in the longitudinal direction, and the substrate on which the silicon nitride layer has been formed is taken up again in a roll shape.

Preferably, the organic layer is a layer obtained by crosslinking a (meth)acrylate-based organic compound having three or more functional groups.

Preferably, the surfactant is a silicon-based surfactant.

The present invention provides a functional film comprising: one or more sets of an organic layer not containing halogen, a silicon nitride layer formed on the organic layer, and an organic/silicon nitride-mixed layer that is formed between the organic layer and the silicon nitride layer and does not contain halogen.

In the functional film of the invention, preferably, the organic layer contains a surfactant in an amount of 0.01% by weight to 10% by weight.

Preferably, the organic layer has a thickness of 0.5 μm to 5 μm.

Preferably, the organic layer is a layer obtained by crosslinking a (meth)acrylate-based organic compound having three or more functional groups.

According to the functional film manufacturing method and the functional film having the configuration as above, it is possible to stably obtain a high-performance functional film such as a gas barrier film having high gas barrier performance in which the water vapor permeability is less than 1×10⁻³ [g/(m²·day)].

### BRIEF DESCRIPTION OF THE DRAWINGS

FIGS. 1A to 1C are views each schematically showing an example of a gas barrier film using a functional film of the present invention.

FIGS. 2A and 2B are views schematically showing together an example of a manufacturing apparatus for performing a functional film manufacturing method of the present invention. FIG. 2A is an organic layer-forming apparatus, and FIG. 2B is a silicon nitride layer-forming apparatus.

### DETAILED DESCRIPTION OF THE INVENTION

Hereinafter, a functional film manufacturing method and a functional film of the present invention will be described in detail based on preferred examples illustrated in the attached drawings.

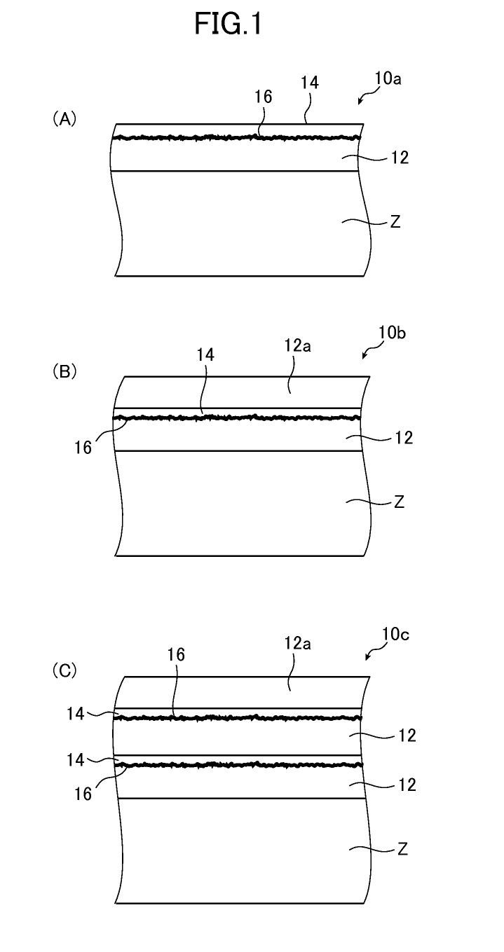

FIG. 1A schematically shows an example of a gas barrier film using the functional film of the present invention.

A gas barrier film 10a shown in FIG. 1A basically has a support Z as a substrate such as a plastic film which will be described later, an organic layer 12 on (a surface of) the support Z, and a silicon nitride layer 14 on the organic layer 12. In the gas barrier film 10a, a mixed layer 16 formed of a mixture of a component of the organic layer 12 and silicon nitride (a component of the silicon nitride layer 14) is disposed between the organic layer 12 and the silicon nitride layer 14.

Although the details will be described later, the organic layer 12 and the mixed layer 16 as underlayers of the silicon nitride layer 14 do not contain halogen (a compound containing a halogen atom (element)). That is, the organic layer 12 and the mixed layer 16 are halogen-free layers.

The gas barrier film 10a is manufactured by the functional film manufacturing method of the present invention that will be described later.

The gas barrier film 10a (functional film) of the present invention is not limited to the structure shown in FIG. 1A as long as it has the organic layer 12, the silicon nitride layer 14 on the organic layer 12, and the mixed layer 16 between the organic layer 12 and the silicon nitride layer 14, and various layer structures are possible.

For example, as in a gas barrier film lob shown in FIG. 1B, as a preferred embodiment, an organic protective layer 12a which is provided mainly for protecting the silicon nitride layer 14 may be disposed on the silicon nitride layer 14 (as an uppermost layer).

In order to obtain higher gas barrier performance, as in a gas barrier film 10c shown in FIG. 1C, the film can have a structure in which plural sets of the organic layer 12, the silicon nitride layer 14, and the mixed layer 16 therebetween are disposed (two sets in the example shown in FIG. 1C). Moreover, in the example shown in FIG. 1C, as a preferred embodiment, similarly to the example shown in FIG. 1B, the organic protective layer 12a serving mainly to protect the silicon nitride layer 14 is disposed as the uppermost layer.

In the present invention, the organic protective layer 12a as the uppermost layer may contain halogen.

That is, in the present invention, the organic layer 12 not containing halogen is the organic layer 12 being an underlayer of the silicon nitride layer 14. In other words, in the present invention, the mixed layer 16 is interposed between the silicon nitride layer 14 and the organic layer 12 not containing halogen.

Although the details will be describe later, in the functional film manufacturing method of the present invention, the organic layer 12 not containing halogen is formed on the substrate surface, and the silicon nitride layer 14 (as well as the mixed layer 16 at the same time) is formed on the organic layer 12 by plasma CVD.

More specifically, in the manufacturing method of the present invention, as an example, the support Z such as a plastic film is used as a substrate, and the organic layer 12 and the silicon nitride layer 14 are formed on the substrate. As a result, for example, the gas barrier film 10a (functional film) of the present invention that has the organic layer 12, the silicon nitride layer 14, and the mixed layer 16 as shown in FIG. 1A is manufactured.

As another example, in the manufacturing method of the present invention, the support Z on which one or more sets of the organic layer 12, the silicon nitride layer 14, and the mixed layer 16 are formed is used as a substrate. Thus, a gas barrier film like the gas barrier film 10c having plural sets of the organic layer 12, the silicon nitride layer 14, and the mixed layer 16 as shown in FIG. 1C may be manufactured. That is, in the manufacturing method of the present invention, the functional film of the present invention may be manufactured using the functional film of the present invention as a substrate.

The functional film of the present invention is not limited to a gas barrier film.

That is, the present invention can be used in various ways for known functional films such as various optical films including optical filters and antireflection films. However, although the detail will be described later, according to the present invention, it is possible to form the silicon nitride layer 14 which is deposited over the entire surface of the underlayer with no ultrafine pinhole. Accordingly, the present invention is advantageously used for a gas barrier film of which the performance significantly deteriorates due to voids in the silicon nitride layer 14.

In the present invention, the support Z (substrate (base)) is not limited, and various known sheet-like substances which are used as supports of functional films such as gas barrier films can be used.

It is preferable to use a long, sheet-like support Z (web-like support Z) such that the organic layer 12 and the silicon nitride layer 14 can be formed by Roll-to-Roll which will be described later.

Specific and preferable examples of the support Z include plastic films formed of various plastics (polymer materials) such as polyethylene terephthalate (PET), polyethylene naphthalate (PEN), polyethylene, polypropylene, polystyrene, polyamide, polyvinyl chloride, polycarbonate, polyacrylonitrile, polyimide, polyacrylate, and polymethacrylate.

Moreover, in the present invention, the above plastic film having one or more layers (films)) for obtaining various functions, such as a protective layer, an adhesive layer, a light reflection layer, an antireflection layer, a light shielding layer, a planarizing layer, a buffer layer, and a stress relaxation layer, as formed on the surface of the plastic film may be used as the support Z (substrate).

The organic layer 12 is formed on the support Z.

The organic layer 12 is a layer formed of an organic compound (layer (film) containing an organic compound as a main component), and is basically obtained by crosslinking (polymerizing) a monomer and/or an oligomer. The organic layer 12 functions as a base layer for appropriately forming the silicon nitride layer 14 which will be described later. The silicon nitride layer 14 is a layer that exhibits the intended functions such as gas barrier properties.

In the present invention, the organic layer 12 does not contain halogen.

Although the detail will be describe later, in the manufacturing method of the present invention, the organic layer 12 is generally formed by preparing a coating material containing an organic compound to be the organic layer 12, applying and drying the coating material, and then crosslinking the organic compound.

Generally, the coating material is prepared by mixing/dissolving (dispersing) an organic solvent, an organic compound that becomes the organic layer 12 by crosslinking, and a surfactant that improves properties of the coating material to cover the support surface (substrate surface) or to embed irregularities at the surface of the support Z or foreign substances adhered to the surface of the support Z.

Accordingly, in the present invention, the coating material forming the organic layer 12 is prepared using an organic compound not containing halogen or a surfactant not containing halogen, such as a silicon-based surfactant. This point will be described later in detail.

The thickness of the organic layer 12 is not limited, but it is preferable to adjust the thickness to be 0.5 μm to 5 μm.

When the thickness of the organic layer 12 is adjusted to be equal to or greater than 0.5 μm, irregularities at the surface of the support Z or foreign substances adhered to the surface of the support Z can be appropriately embedded. As a result, the surface of the organic layer 12, that is, the surface on which the silicon nitride layer 14 is to be formed is flattened, and the aforementioned “shadow” portions at which it is difficult to form (deposit) the silicon nitride layer 14 can be appropriately eliminated.

Moreover, when the thickness of the organic layer 12 is adjusted to be equal to or less than 5 μm, it is possible to prevent problems, such as cracking of the organic layer 12 or curling of the gas barrier film 10a, which may be caused by too large thickness of the organic layer 12.

Further, as shown in the examples illustrated in FIGS. 1B and FIG. 1C, when the film has plural organic layers 12 (including the organic protective layer 12a), the respective organic layers 12 may be the same or different in thickness.

In the present invention, the silicon nitride layer 14 is formed on the organic layer 12 by plasma CVD, although the details will be described later.

At this time, in the case where the organic layer contains halogen, when the silicon nitride layer is formed by plasma CVD, the organic layer is etched by plasma, and halogen is released from the organic layer. In the plasma (in the film formation system), the halogen binds to silicon which is generated by decomposition of film-forming gas (silane). As a result, formation and film deposition of silicon nitride is hindered, and many ultrafine pinholes are formed in the resulting silicon nitride layer.

When the organic layer contains halogen, the thicker the organic layer is, the more halogen is released from the organic layer, and accordingly, pinholes tend to be formed.

In contrast, in the present invention, the organic layer 12 does not contain halogen. Since the organic layer 12 does not contain halogen, the formation of pinholes in the silicon nitride layer 14 can be prevented.

Specifically, in the present invention, the thickness of the organic layer 12 can be set to a sufficient level without considering the possible formation of pinholes in the silicon nitride layer 14, whereby the effects imparted by the organic layer 12 such as flattening the surface and embedding foreign substances can be sufficiently attained.

In view of the above points, in the present invention, the thickness of the organic layer 12 is preferably adjusted to 0.5 to 5 μm as described above, more preferably to 1 μm to 3 and particularly preferably to 1.5 μm to 2.5 μm.

In the gas barrier film 10a of the present invention, the material forming the organic layer 12 is not limited, and various known organic compounds (resins/polymer compounds) can be used as long as they do not contain halogen.

Specific and preferable examples of the materials include films formed of thermoplastic resins, such as polyester, acrylic resins, methacrylic resins, methacrylic acid-maleic acid copolymers, polystyrene, polyimide, polyamide, polyamide-imide, polyetherimide, cellulose acylate, polyurethane, polyether ether ketone, polycarbonate, alicyclic polyolefin, polyarylate, polyether sulfone, polysulfone, fluorene ring-modified polycarbonate, alicyclic-modified polycarbonate, fluorene ring-modified polyester, and acryloyl compounds; polysiloxane; and other organic silicon compounds.

Among these, in view of having a high Tg, excellence in strength, and the like, an organic layer 12 composed of polymers of radically-polymerizable compound and/or cationically-polymerizable compound having an ether group as a functional group is preferable.

In particular, in view of, in addition to the high Tg and excellence in strength, a low refractive index and excellence in optical properties, acrylic resins or methacrylic resins containing polymers of acrylate and/or methacrylate monomers or oligomers as a main component are preferable for the organic layer 12.

Among these, acrylic resins or methacrylic resins containing, as a main component, polymers of acrylate and/or methacrylate monomers or oligomers having three or more functional groups, such as trimethylolpropane tri(meth)acrylate (TMPTA) and dipentaerythritol hexa(meth)acrylate (DPHA), are particularly preferable, since these have a high Tg and exhibit excellent etching resistance during the formation of the silicon nitride layer 14.

In the manufacturing method of the present invention, the silicon nitride layer 14 is formed on the organic layer 12 by plasma CVD. During the formation of the silicon nitride layer 14, the organic layer 12 is etched by plasma, and consequentially, the mixed layer 16 in which the material forming the organic layer 12 is mixed with silicon nitride is inevitably formed.

Needless to say, the mixed layer 16 does not exhibit gas barrier properties that the silicon nitride layer 14 has. Therefore, the thickness of the silicon nitride layer 14 is substantially decreased with increasing thickness of the mixed layer 16. Moreover, as described above, due to the etching of the organic layer 12 that causes the formation of the mixed layer 16, ultrafine pinholes are formed in the silicon nitride layer 14.

In contrast, (meth)acrylic resins formed of (meth)acrylate having three or more functional groups have a high Tg and high strength, and accordingly, they can inhibit the etching caused by plasma. Therefore, the (meth)acrylic resins are preferably used.

As described above, in the gas barrier film 10a of the present invention, the organic layer 12 is generally formed of a coating material containing an organic solvent, an organic compound to be the organic layer 12, and a surfactant. Therefore, the organic layer 12 generally contains a surfactant.

The amount of the surfactant contained in the organic layer 12 is not limited, but is preferably 0.01% by weight to 10% by weight. That is, in the manufacturing method of the present invention that will be described later, it is preferable to form the organic layer 12 by using a coating material containing a surfactant in an amount of 0.01% by weight to 10% by weight in terms of the concentration when an organic solvent is excluded.

The surfactant to be used is a surfactant not containing halogen, such as a silicon-based surfactant.

The above point will be described later in detail.

The silicon nitride layer 14 is a layer formed of silicon nitride (layer (film) containing silicon nitride as a main component). Moreover, in the present invention, the silicon nitride layer 14 is formed by plasma CVD.

In the gas barrier film 10a, the silicon nitride layer 14 is a layer mainly exhibiting intended gas barrier properties. That is, in the functional film of the present invention, the silicon nitride layer 14 mainly exhibits intended functions such as gas barrier properties.

In the present invention, the thickness of the silicon nitride layer 14 is not limited. That is, the film thickness of the silicon nitride layer 14 may be suitably determined depending on the material forming the silicon nitride layer 14 and adjusted so as to exhibit intended gas barrier properties (functions). According to the study conducted by the present inventor, it is preferable to adjust the thickness of the silicon nitride layer 14 to be 15 nm to 200 nm.

When the thickness of the silicon nitride layer 14 is adjusted to be equal to or greater than 15 nm, it is possible to form the silicon nitride layer 14 that can stably exhibit sufficient gas barrier performance (intended performance). Generally, the silicon nitride layer 14 is brittle, and if the silicon nitride layer 14 is too thick, cracking, crazing, coming-off, and the like may occur. However, by adjusting the thickness of the silicon nitride layer 14 to be equal to or less than 200 nm, cracking can be prevented.

In view of the above points, the thickness of the silicon nitride layer 14 is preferably 15 nm to 100 nm, and particularly preferably 20 nm to 75 nm.

In the gas barrier film 10a of the present invention, the mixed layer 16 is present between the organic layer 12 and the silicon nitride layer 14.

Although the details will be describe later, in the manufacturing method of the present invention, after the organic layer 12 is formed, the silicon nitride layer 14 is formed by plasma CVD. When the silicon nitride layer 14 is formed on the surface of the organic layer 12 by plasma CVD, the organic layer 12 is etched by plasma of CVD. Due to the etching of the organic layer 12, the mixed layer 16 in which the material forming the organic layer 12 is mixed with silicon nitride is inevitably formed concomitantly with the film deposition of silicon nitride.

The amount of the organic materials in the mixed layer 16 decreases as the formation of the silicon nitride layer 14 (the film deposition of silicon nitride) progresses, and finally, a pure silicon nitride layer 14 not containing the organic material is formed.

In the present invention, the mixed layer 16 is inevitably formed due to the etching of the organic layer 12 that is caused by plasma of CVD used for forming the silicon nitride layer 14.

Accordingly, the thickness of the mixed layer 16 varies depending on the material forming the organic layer 12 or the conditions under which the silicon nitride layer 14 is formed. According to the study conducted by the present inventor, the thickness of the mixed layer 16 is generally about several nm and usually equal to or less than 10 nm at most.

In the present invention, the organic layer 12 does not contain halogen, and the silicon nitride layer 14 is formed on the organic layer 12.

Accordingly, in the gas barrier film 10a (functional film) of the present invention, the mixed layer 16 also does not contain halogen (the mixed layer 16 is free of halogen).

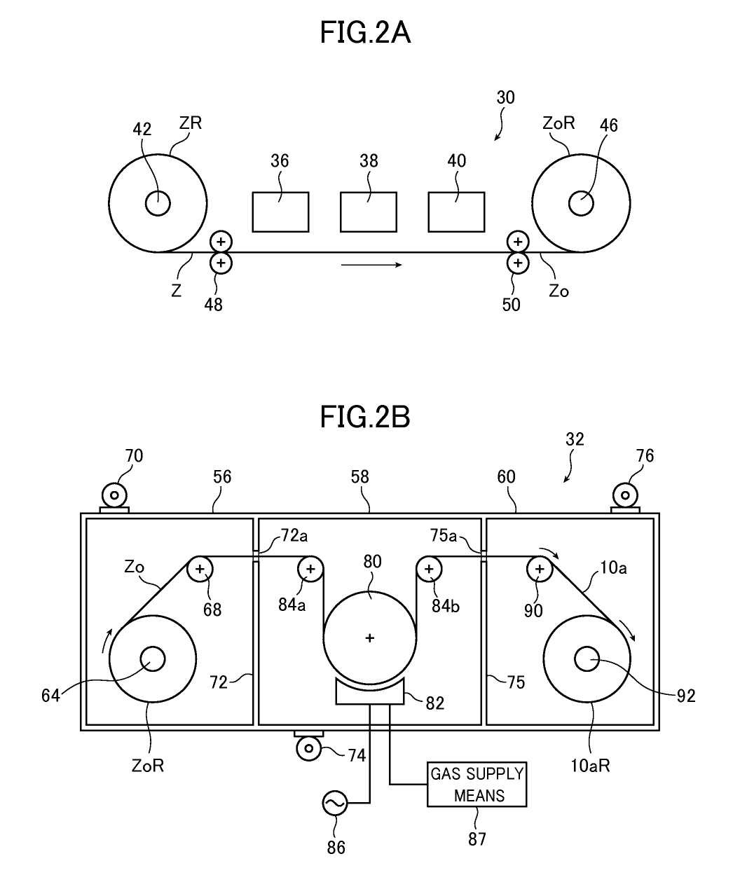

FIGS. 2A and 2B schematically show together an example of a manufacturing apparatus for manufacturing the aforementioned gas barrier film 10a by the functional film manufacturing method of the present invention.

The manufacturing apparatus includes an organic film-forming apparatus 30 for forming the organic layer 12 and an inorganic film-forming apparatus 32 for forming the silicon nitride layer 14. FIG. 2A illustrates the organic film-forming apparatus 30 and FIG. 2B illustrates the inorganic film-forming apparatus 32.

The organic film-forming apparatus 30 and the inorganic film-forming apparatus 32 shown in FIGS. 2A and 2B are apparatuses that each form a film by so-called Roll-to-Roll (hereinafter, also referred to as “RtoR”) in which, from a material roll obtained by taking up a long material on which a film is to be formed, the material on which a film is to be formed is fed; a film is formed while the material on which a film is to be formed is transported in a longitudinal direction; and the material on which a film has been formed is again taken up into a roll shape.

The RtoR makes it possible to manufacture a highly efficient gas barrier film 10a (functional film) with high productivity.

The manufacturing method of the present invention is not limited to the method of manufacturing a functional film such as a gas barrier film by means of the RtoR using the long support Z. That is, the manufacturing method of the present invention may be a method of manufacturing a functional film by means of a so-called sheet-type (batch-type) film forming method using a cut sheet-like support Z.

However, in the present invention, in view of obtaining greater effects of the invention and other reasons, it is preferable that the gas barrier film 10a and the like be manufactured by means of the RtoR. This point will be described later in detail.

Even when the cut sheet-like support Z is used, the method of forming the organic layer 12, the silicon nitride layer 14, and the protective organic layer 12a which is the uppermost organic layer is basically the same as the manufacturing method by means of the RtoR described below.

The organic film-forming apparatus 30 shown in FIG. 2A is an apparatus in which the long support Z (a material on which a film is to be formed) is, while being transported in the longitudinal direction, coated with a coating material that is to be the organic layer 12, the resultant coating film is dried, and the organic compound contained in the coating film is crosslinked and cured by means of light irradiation to thereby form the organic layer 12.

The organic film-forming apparatus 30 includes, for example, coating means 36, drying means 38, light irradiation means 40, a rotary shaft 42, a take-up shaft 46, and pairs of transport rollers 48 and 50.

In addition to the members shown in the drawing, the organic film-forming apparatus 30 may include various members such as a pair of transport rollers, a guide member for a support Zo, and various sensors, as installed in known apparatuses which perform film formation by coating while transporting a long material on which a film is to be formed.

In the organic film-forming apparatus 30, a support roll ZR obtained by taking up the long support Z is loaded onto the rotary shaft 42.

After the support roll ZR is loaded onto the rotary shaft 42, the support Z is drawn from the support roll ZR and allowed to pass through (is fed along) a predetermined transport path that goes through the pair of transport rollers 48, below the coating means 36, the drying means 38 and the light irradiation means 40, and through the pair of transport rollers 50, and then reaches the take-up shaft 46.

In the organic film-forming apparatus 30, the feeding of the support Z from the support roll ZR is synchronized with the taking-up by the take-up shaft 46 of the support Zo on which the organic layer 12 has been formed. Thus, while being transported in the longitudinal direction along the predetermined transport path, the long support Z is coated with a coating material that is to be the organic layer 12 by the coating means 36, and the coating material is dried by the drying means 38 and cured by the light irradiation means 40, whereby the organic layer 12 is formed.

The coating means 36 is for coating the surface of the support Z with a coating material that is to be the organic layer 12 and is prepared in advance.

The coating material contains an organic compound (monomer/oligomer) which becomes the organic layer 12 by crosslinking and polymerization, an organic solvent, and a surfactant (surface conditioner). Moreover, if necessary, various additives used for forming the organic layer 12, such as a silane coupling agent and a polymerization initiator (crosslinking agent), are appropriately added to the coating material.

In the present invention, the organic layer 12 (excluding the organic protective layer 12a) does not contain halogen.

Accordingly, as components added to the coating material that is to be the organic layer 12, except for components to be removed by drying or crosslinking like an organic solvent, substances not containing halogen (substances not including compounds having a halogen atom) are used. That is, as the organic compound that is to be the organic layer 12, for example, organic compounds not containing a halogen atom, such as the aforementioned TMPTA or DPHA, are used. Moreover, as the surfactant, for example, surfactants formed of compounds not containing a halogen atom, such as silicon-based surfactants, are used.

In the manufacturing method of the present invention, the silicon nitride layer 14 is formed by plasma CVD on the organic layer 12 that does not contain halogen. Owing to the configuration as described above, in manufacturing the gas barrier film or the like that uses the silicon nitride layer 14 as a gas barrier layer (functional layer), the present invention makes it possible to stably manufacture extremely high performance products by plasma CVD with high productivity.

As a silicon source for forming the silicon nitride layer 14 by plasma CVD, silane is generally used. That is, the silicon nitride layer 14 is generally formed by plasma CVD using film-forming gas that includes a silane gas as a silicon source.

As described in JP 2009-262490 A or JP 2011-46060 A, there is known a conventional organic/inorganic laminate-type gas barrier film (functional film) which is obtained by forming an organic layer on a surface of a substrate such as a plastic film and forming an inorganic layer on the organic layer.

In the organic/inorganic laminate-type gas barrier film, the organic Layer formed on the substrate surface is provided so as to embed irregularities at the substrate and foreign substances, a lubricant, and the like adhered to the substrate surface to thereby flatten the surface on which the inorganic layer is to be formed.

Meanwhile, as a gas barrier layer that exhibits excellent gas barrier properties, the silicon nitride layer (film) 14 is known.

The plasma CVD is used for forming the silicon nitride layer 14 because this method can achieve high productivity and form high-density films.

A gas barrier film, which is obtained by forming the silicon nitride layer on the organic layer by plasma CVD, can stably exhibit intended performance to the extent that the water vapor permeability (gas barrier properties) is higher than 1×10⁻³ [g/(m²·day)].

However, if a gas barrier film is manufactured with the intention of obtaining gas barrier properties of higher level than the above, intended gas barrier properties often cannot be obtained.

The present inventor conducted an intensive study to find the reason. As a result, they found that components contained in the organic layer are the important factor for obtaining a high degree of gas barrier properties.

As described above, when a film is formed on the organic layer by plasma CVD, the organic layer is etched by plasma, whereby the above-described organic/inorganic mixed layer is formed.

When the silicon nitride layer is formed on the surface of the organic layer containing halogen by plasma CVD, halogen is released from the etched organic layer into plasma. The halogen released into plasma binds to silicon generated by decomposition of film-forming gas (silane) that is caused by plasma, and accordingly, silicon halide such as silicon chloride or silicon fluoride is generated. Halogen is more active than silicon. Therefore, binding of halogen to silicon hinders the generation of silicon nitride (binding of silicon to nitrogen). Consequently, silicon nitride is not deposited at positions where halogen is present in the organic layer, and ultrafine pinholes of nanometer-order are formed at these positions.

In this way, when the organic layer contains halogen, many fine pinholes are formed in the silicon nitride layer formed by plasma CVD.

In particular, when a surfactant containing halogen, such as a fluorosurfactant, is used as a surfactant, the ultrafine pinholes tend to be formed.

As described above, in the organic/inorganic laminate-type gas barrier film, the organic layer is formed to embed irregularities at the surface of the support Z (substrate surface) or foreign substances adhered to the surface of the support Z and to flatten the surface on which the inorganic layer is to be formed.

In order to cover with the coating material the entire surface of the support Z (substrate) including foreign substances and the like, it is necessary to lower the surface tension of the coating material that is to be the organic layer so as to improve covering properties by the coating material and properties to embed irregularities and foreign substances. Therefore, it is preferable to add a surfactant to the coating material forming the organic layer.

Due to the nature, a large part of the surfactant added to the coating material is present in the vicinity of the surface (surface layer) of the dried coating film. Moreover, due to its self-aggregation properties, the surfactant aggregates in the vicinity of the surface of the coating film. That is, in the case of using the coating material containing a surfactant, no matter how evenly the coating material is mixed, the coating film obtained by drying the coating material inevitably has a surfactant concentration gradient in which the concentration increases from the side closer to the support Z toward the surface. Moreover, even at the surface, a surfactant concentration gradient locally exists in the surface area.

At the coating film surface, a concavity is formed at the portion where the surfactant aggregates due to a difference in surface tension between this portion and an area therearound. The portion where the surfactant aggregates can be observed with an Atomic Force Microscope (AFM).

When the coating film as above is cured (when the organic compound is crosslinked), the organic layer is formed with the surfactant concentration gradient being maintained.

Needless to say, the organic layer is etched by plasma from the surface thereof. Accordingly, when the silicon nitride layer is formed by plasma CVD on the organic layer containing, for example, a fluorosurfactant, a large amount of fluorine derived from the surfactant is released into plasma from the etched organic layer. In particular, at the portion where the surfactant aggregates, a large amount of fluorine is released from the etched organic layer. Fluorine binds more preferentially to silicon than to nitrogen, and hinders formation and film deposition of silicon nitride.

Consequently, in the formed silicon nitride layer, many fine pinholes having an inverted cone shape in which the diameter increases toward the surface are formed at the coating film surface mainly at and around the positions where the surfactant has aggregated. When the film thickness of the silicon nitride layer is, for example, 30 nm to 50 nm, these pinholes are to be ultrafine pinholes of which the bottom diameter (at the surface of the silicon nitride layer 14) is about several nm to 100 nm.

If required water vapor permeability is higher than 1×10⁻³ [g/(m²·day)], halogen-induced pinholes contained in the organic layer as described above do not exert a great influence on the gas barrier properties. However, when gas barrier properties of higher level than the above are required, due to the influence of the pinholes, intended gas barrier properties are not easily obtained.

In contrast, in the present invention, the organic layer 12 does not contain halogen (a compound containing a halogen atom). Accordingly, even when the silicon nitride layer 14 is formed by plasma CVD on the organic layer 12, halogen-induced pinholes are not formed.

Therefore, according to the present invention, in an organic/inorganic laminate-type functional film which is obtained by forming a silicon nitride layer on an organic layer, a high-performance functional film of which the performance does not deteriorate by pinholes in the silicon nitride layer 14, such as a high-performance gas barrier film having a water vapor permeability of less than 1×10⁻³ [g/(m²·day)], can be stably obtained.

The formation of halogen-induced pinholes is a phenomenon unique to the system in which a silicon nitride layer is formed on the surface of an organic layer by plasma CVD.

That is, in a film formation method such as vacuum deposition or sputtering, even if a silicon nitride layer is formed on an organic layer containing halogen, pinholes are not formed in the organic layer.

In vacuum deposition, plasma is not generated at the time of film formation. Therefore, even if a silicon nitride layer is formed on an organic layer, the organic layer is not etched by plasma. Accordingly, in the vacuum deposition, even if the organic layer contains halogen, halogen is not released from the organic layer into the film formation system, and halogen-induced pinholes are not formed.

In sputtering, plasma is generated to form a film. However, in sputtering (including reactive sputtering), plasma is generated in the vicinity of a target and does not reach the surface on which a film is to be formed. That is, the organic layer is not etched by plasma, and only silicon nitride to be formed into a film reaches the surface of the organic layer. Accordingly, in sputtering, even if the organic layer contains halogen, halogen is not released from the organic layer into the film formation system, and halogen-induced pinholes are not formed.

As described above, the coating means 36 coats the surface of the support Z (substrate) with the coating material that is to be the organic layer 12. The coating material is prepared by mixing/dissolving (dispersing) an organic solvent, an organic compound that becomes the organic layer 12 by crosslinking, a surfactant, and the like together.

Moreover, as described above, in the gas barrier film 10a of the present invention, the organic layer 12 does not contain halogen (excluding components derived from inevitable impurities). Accordingly, as components added to the coating material to be applied to the support Z by the coating means 36, substances not containing halogen (compounds not containing a halogen atom) are used, although this does not apply to components that are removed by drying or crosslinking to be performed later, such as an organic solvent.

As the organic compound that is to be the organic layer 12 by crosslinking (polymerization), various compounds not containing halogen can be used.

Among these, as described in the explanation on the material for forming the organic layer 12, radically-polymerizable compounds and/or cationically-polymerizable compounds having an ether group as a functional group are preferred. Among these, acrylate and/or methacrylate monomers or oligomers are particularly preferred. Of these, particularly preferable examples thereof include acrylate and/or methacrylate monomers or oligomers having three or more functional groups.

As the surfactant, various surfactants not containing halogen, such as silicon-based surfactants, can be used. Among these, it is preferable to use a surfactant of silicon-based as in the case of the silicon nitride layer 14.

The concentration of the surfactant in the coating material for forming the organic layer 12 is not limited. However, it is preferable for the coating material to contain the surfactant at a concentration of 0.01% by weight to 10% by weight in terms of the concentration when the organic solvent is excluded (the concentration determined when the total amount of the components excluding the organic solvent is regarded as being 100% by weight).

The coating material that contains the surfactant in an amount of 0.01% by weight or more is preferable since surface tension of the coating material can be adjusted to an appropriate level from coating to drying, and the entire substrate surface as well as irregularities or foreign substances can be covered with the organic layer 12 without leaving voids.

Moreover, it is preferable to adjust the content of the surfactant in the coating material to be equal to or less than 10% by weight because, for instance, phase separation of the coating material can be advantageously suppressed and the proportion of a main monomer can be increased, whereby etching resistance, which is a good feature imparted by a monomer having many functional groups, is less likely to be affected.

In view of the above points, the content of the surfactant in the coating material is preferably 0.05% by weight to 3% by weight.

The coating material for forming the organic layer 12 may be prepared by a known method by dissolving (dispersing) the organic compound that is to be the organic layer 12, the surfactant, and the like in an organic solvent by a known method.

The organic solvent used for preparing the coating material is not limited, and it is possible to use various organic solvents used for forming an organic layer in an organic/inorganic laminate-type functional film, such as methyl ethyl ketone (MEK), cyclohexanone, isopropyl alcohol, and acetone.

Moreover, if necessary, various additives used for forming the organic layer 12, such as a surfactant, a silane coupling agent, and a photopolymerization initiator, may be appropriately added to the coating material for forming the organic layer 12.

In the manufacturing method of the present invention, as to those additive components, in the case where a component added is one that remains in the organic layer 12 after drying or crosslinking, a halogen-free component is employed.

The viscosity of the coating material to be applied onto the support Z is not limited. However, considering the above points, the viscosity is preferably 0.6 cP to 30 cP, and particularly preferably 1 cP to 10 cP. Accordingly, it is preferable to adjust the solid content concentration or the like of the coating material such that the viscosity falls in the above range.

In order to cover the surface of the support Z as well as foreign substances, irregularities, and the like on the surface of the support Z without leaving voids, the support Z needs to be coated with the coating material such that the support Z does not have an uncoated portion. That is, the entire surface of the support Z (an area over which the silicon nitride layer 14 is to be formed) as well as foreign substances and the like needs to be dipped into the coating material without leaving voids. Therefore, it is preferable for the coating material to have a viscosity that is somewhat low. Moreover, when the viscosity of the coating material is too high due to, for instance, an excessively high solid content concentration of a coating solution, a stripe failure occurs, and as a result, lack of the organic layer is easily caused.

If the viscosity of the coating material is controlled to be within the above range, the aforementioned problems can be avoided reliably, and the entire surface of the support Z can be appropriately coated with the coating material.

As described above, in the organic film-forming apparatus 30, while the long support Z is transported in the longitudinal direction, the surface of the support Z is coated with the coating material by the coating means 36, the coating material is dried by the drying means 38, and the dried coating material is cured by the light irradiation means 40, whereby the organic layer 12 is formed.

In the coating means 36, the method for coating the support Z with the coating material is not limited.

Accordingly, for coating of the coating material, any of known coating methods including a die coating method, a dip coating method, an air knife coating method, a curtain coating method, a roller coating method, a wire bar coating method, a gravure coating method, and a slide coating method can be used.

Among these, a die coating method is preferably used for the reasons that the surface of the support Z (particularly, the silicon nitride layer when plural organic layers 12 are formed) is not damaged since the support Z can be coated with the coating material in a noncontact manner; and irregularities, foreign substances, and the like on the surface of the support Z can be excellently embedded by forming beads (liquid pool), and for other reasons.

The amount of the coating material to be applied onto the support Z by the coating means 36 is preferably 5 cc/m² to 50 cc/m².

When the amount of the coating material is adjusted to be equal to or more than 5 cc/m², the entire surface of the support Z can be dipped into the coating material without leaving voids as described above, and the surface of the support Z can be more reliably covered with the organic layer 12 without any space. When the amount of the coating material is adjusted to be equal to or less than 50 cc/m², it is possible to advantageously avoid problems such as the decrease in productivity caused by the increase in drying load due to the excessive amount of the coating material, and the decrease in effects of the coating film resulting from the increase in the amount of a residual solvent. Depending on the coating method, if the amount of the coating material is too large, destabilization of a bead portion that is called liquid dripping may be caused. However, if the amount of the coating material is adjusted to be equal to or less than 50 cc/m², such a problem can also be advantageously avoided.

In view of the above points, the amount of the coating material to be applied onto the support Z is more preferably 5 cc/m² to 30 cc/m².

As described above, in the gas barrier film 10a of the present invention, the thickness of the organic layer 12 (organic protective layer 12a) is preferably 0.5 μm to 5 μm.

Accordingly, in the present invention, it is preferable to prepare the coating material such that the thickness of the organic layer 12 (that is substantially the same as the thickness of a dry film formed of the coating material) is 0.5 μm to 5 μm when the coating material is applied in an amount equal to or more than 5 cc/m². In other words, it is preferable that the coating means 36 coat the support Z with the coating material such that the thickness of the dry film is 0.5 μm to 5 μm when the coating material is applied in an amount equal to or more than 5 cc/m² according to the type of the coating material.

As described above, the support Z is then transported to the drying means 38, and the coating material coated by the coating means 36 is dried.

A method of drying the coating material by the drying means 38 is not limited, and any known drying means can be used, as long as the coating material can be dried up (an organic solvent is completely removed) before the support Z reaches the light irradiation means 40 so that the state capable of crosslinking is established. Examples of the drying means include drying by heating using a heater, and drying by heating using hot air.

The support Z is then transported to the light irradiation means 40. The light irradiation means 40 irradiates the coating material, which has been coated by the coating means 36 and dried by the drying means 38, with UV (UV light), visible light, or the like to crosslink (polymerize) and cure the organic compound (monomers or oligomers of the organic compound) contained in the coating material, thereby forming the organic layer 12.

When the coating film is cured by the light irradiation means 40, the area of the support Z to be irradiated with light by the light irradiation means 40 may be optionally placed in an inert atmosphere (oxygen-free atmosphere) by nitrogen purging and the like. Moreover, the temperature of the support Z, that is, the temperature of the coating film may be optionally adjusted during curing by using a backup roller and the like that comes into contact with the back surface of the support Z.

In the present invention, the method of crosslinking of the organic compound that is to be the organic layer 12 is not limited to photopolymerization. That is, for crosslinking of the organic compound, it is possible to use various methods appropriate for a type of the organic compound that is to be the organic layer 12, such as heating polymerization, electron beam polymerization, and plasma polymerization.

In the present invention, as described above, acryl-based resins such as acrylic resins and methacrylic resins are preferably used as the organic layer 12, and hence photopolymerization is preferably used.

The support Z on which the organic layer 12 has been formed in the above manner (hereinafter, the support Z on which the organic layer 12 has been formed is referred to as “support Zo”) is transported as interposed between the pair of transport rollers 50 and reaches the take-up shaft 46. The support Zo is taken up again by the take-up shaft 46 in a roll shape and becomes a roll ZoR which is obtained by taking up the support Zo.

The roll ZoR is supplied to the inorganic film-forming apparatus 32 (a supply chamber 56 thereof) shown in FIG. 2B.

The inorganic film-forming apparatus 32 is used to form the silicon nitride layer (film) 14 on the surface of the organic layer 12 (support Zo) by plasma CVD, and includes the supply chamber 56, a film formation chamber 58, and a take-up chamber 60.

In addition to the members illustrated in the drawing, the inorganic film-forming apparatus 32 may further include various members such as a pair of transport rollers, a guide member which restricts the widthwise position of the support Zo, and various sensors, as installed in known apparatuses that perform film formation by a vapor-phase deposition method while transporting a long material on which a film is to be formed.

The supply chamber 56 includes a rotary shaft 64, a guide roller 68, and vacuum exhaust means 70.

In the inorganic film-forming apparatus 32, the roll ZoR obtained by taking up the support Zo is loaded onto the rotary shaft 64 of the supply chamber 56.

After the roll ZoR is loaded onto the rotary shaft 64, the support Zo is allowed to pass through (the support Zo is fed along) a predetermined transport path from the supply chamber 56, via the film formation chamber 58, to a take-up shaft 92 of the take-up chamber 60. Also in the inorganic film-forming apparatus 32, the feeding of the support Zo from the roll ZoR is synchronized with the taking-up by the take-up shaft 92 of the support Zo on which the silicon nitride layer has been formed (that is, the gas barrier film 10a), and the silicon nitride layer 14 is continuously formed on the support Zo in the film formation chamber 58 while the support Zo is transported in the longitudinal direction.

In the supply chamber 56, the rotary shaft 64 is rotated clockwise in the drawing by a power source not shown in the drawing, whereby the support Zo is fed from the support roll ZoR. The support Zo fed from the roll ZoR is guided to follow the predetermined path by the guide roller 68 and transported to the film formation chamber 58 through a slit 72a formed in a partition 72.

In the inorganic film-forming apparatus 32 illustrated in the drawing, as a preferred embodiment, the vacuum exhaust means 74 is disposed in the supply chamber 56, and vacuum exhaust means 76 is disposed in the take-up chamber 60. In the inorganic film-forming apparatus 32, during the film formation, each of the vacuum exhaust means maintains the pressure of the supply chamber 56 and the take-up chamber 60 at a predetermined pressure according to the pressure (film formation pressure) of the film formation chamber 58 that will be described later. As a result, the pressure of the film formation chamber 58 (film formation performed in the film formation chamber 58) is prevented from being affected by the pressures of the adjacent chambers.

A type of the vacuum exhaust means 70 is not limited, and it is possible to use various known (vacuum) exhaust means such as vacuum pumps including a turbo pump, a mechanical booster pump, a dry pump, and a rotary pump, as used in apparatuses for film formation in a vacuum. The same applies to the other vacuum exhaust means 74 and 76 which will be described later.

The film formation chamber 58 is used to form the silicon nitride layer 14 on the surface of the support Zo (that is, the surface of the organic layer 12) by plasma CVD.

In the example illustrated in the drawing, the film formation chamber 58 includes a drum 80, a shower electrode 82, guide rollers 84a and 84b, a high-frequency power source 86, gas supply means 87, and the above-described vacuum exhaust means 74.

The support Zo having been transported to the film formation chamber 58 is guided to follow the predetermined path by the guide roller 84a and wound around the drum 80 to be placed at a predetermined position. The support Zo is transported in the longitudinal direction while being held at the predetermined position by the drum 80, and the silicon nitride layer 14 is formed on the support Zo by plasma CVD.

The vacuum exhaust means 74 evacuates the air of the inside of the film formation chamber 58 and establishes a degree of vacuum appropriate for forming the silicon nitride layer 14 by plasma CVD.

The drum 80 is a cylindrical member that rotates counterclockwise in the drawing about the centerline thereof.

The support Zo, which has been supplied from the supply chamber 56, guided to follow the predetermined path by the guide roller 84a, and then wound around the drum 80 to be placed at the predetermined position, is hung on a predetermined area on the circumferential surface of the drum 80. The support Zo is transported along the predetermined transport path while being supported and guided by the drum 80, and the silicon nitride layer 14 is formed on the surface of the support Zo.

The film formation chamber 58 illustrated in the drawing forms the silicon nitride layer 14 on the surface of the support Zo by, for example, Capacitively Coupled Plasma CVD (CCP-CVD). The drum 80 also functions as a counter electrode in CCP-CVD, and constitutes an electrode pair together with the shower electrode 82 (film formation electrode) which will be described later.

Therefore, the drum 80 may be connected to a bias supply for supplying bias power or connected to ground. Alternatively, the connection to the bias supply and the connection to ground may be switchable. Moreover, in order to cool or heat the support Zo, the drum 80 may have temperature regulating means that regulates the temperature of the circumferential surface thereof supporting the support Zo.

The high-frequency power source 86 is a known high-frequency power source used for plasma CVD and supplies plasma excitation power ro the shower electrode 82.

Gas supply means 87 is also known means for supplying film-forming gas (raw material gas/process gas) used for plasma CVD and supplies film-forming gas to the shower electrode 82.

In the present invention, as the film-forming gas, a combination of various known gases can be used, as long as a silicon source is contained therein and the silicon nitride layer can be formed.

Examples of the gas include a combination of silane gas, ammonia gas, and nitrogen gas; a combination of silane gas, ammonia gas, and inert gas; a combination of silane gas, ammonia gas, nitrogen gas, and hydrogen gas; and a combination of silane gas, ammonia gas, inert gas, and hydrogen gas.

The shower electrode 82 is a known shower electrode (shower plate) used for CCP-CVD.

That is, the shower electrode 82 is in the form of a case whose one surface faces the drum 80 and which has a hollow portion in the inside thereof. In the surface facing the drum 80, many through holes (gas supply holes) communicating with the hollow portion are formed.

The gas supply means 87 supplies the film-forming gas to the hollow portion of the shower electrode 82. Accordingly, from the through holes formed in the surface facing the drum 80, the film-forming gas is supplied to the space between the shower electrode 82 as a film formation electrode and the drum 80 as a counter electrode.

While the support Zo is transported in the longitudinal direction while being wound around the drum 80, in the space between the shower electrode 82 and the drum 80, the silicon nitride layer 14 is formed on the organic layer 12 by plasma CVD. Moreover, when the silicon nitride layer 14 is formed, the organic layer 12 is etched by plasma, whereby the mixed layer 16 is formed between the organic layer 12 and the silicon nitride layer 14.

The conditions for forming the silicon nitride layer 14 are not limited, and may be appropriately set according to a type of film-forming gas, an intended film thickness, a film formation rate, and the like.

In the present invention, neither the organic layer 12 nor the mixed layer 16 contains halogen. Accordingly, as described above, the silicon nitride layer 14 of high quality that does not have a halogen-induced ultrafine pinhole is formed.

The ultrafine pinholes, which are formed in the aforementioned silicon nitride layer due to halogen contained in the aforementioned organic layer, are more easily formed in silicon nitride film formation by RtoR than in silicon nitride film formation by a sheet-type method.

Specifically, when a silicon nitride layer is formed by a sheet-type method, as formation of a film proceeds, that is, as film deposition of silicon nitride proceeds, an exposed area of The organic layer is gradually reduced. Accordingly, when the silicon nitride layer is formed by the sheet-type method, the halogen supply source is reduced over time due to deposited silicon nitride.

In contrast, in RtoR, the support Z on which a film has not been formed is constantly supplied to a film formation area (the space between the shower electrode 82 and the drum 80 in the example illustrated in the drawing). In other words, in RtoR, the support Z of which the entire surface has the organic layer 12 formed thereon, that is, the support Z of which the entire surface is a halogen supply source is constantly supplied to the end on the upstream side of the film formation area.

Moreover, in RtoR, as the support Z is transported, the gas also flows along the transport direction of the support Z. Therefore, halogen released to the film formation area at the upstream end flows in the film formation area toward the downstream.

As a result, even after halogen is not released from the organic layer 12 since the organic layer 12 is covered with the silicon nitride layer 14, the surface of the support Z (the surface on which a film is to be formed) is always exposed to halogen and silicon (silane). Consequently, pinholes induced by halogen of the organic layer are more easily formed in RtoR than in the sheet-type method.

In contrast, in the present invention, the organic layer 12 does not contain halogen. Accordingly, even when the silicon nitride layer 14 is formed by RtoR, it is possible to prevent halogen-induced ultrafine pinholes from being formed in the silicon nitride layer 14.

Therefore, in the present invention, by using RtoR as a preferred embodiment, the gas barrier film 10a of high quality and having the silicon nitride layer 14 with no pinhole can be manufactured with high productivity.

In the example illustrated in the drawing, the surface of the shower electrode 82 that faces the drum 80 forms a curved surface parallel to the circumferential surface of the drum 80. However, the present invention is not limited thereto and can use known shower electrodes in various forms.

The CCP-CVD is not limited to the configuration using the shower electrode and may be configured such that the film-forming gas is supplied to the space between the film formation electrode and the drum through a nozzle or the like.

In the manufacturing method of the present invention, the method for forming the silicon nitride layer 14 is not limited to CCP-CVD, and any plasma CVD capable of forming the silicon nitride layer 14, such as an Inductively Coupled Plasma CVD method (ICP-CVD method), can be used.

The support Zo on which the silicon nitride layer 14 has been formed while being supported and transported by the drum 80, that is, the gas barrier film 10a, is guided by the guide roller 84b to follow the predetermined path, and transported to the take-up chamber 60 through a slit 75a formed in a partition 75.

In the example illustrated in the drawing, the take-up chamber 60 includes a guide roller 90, a take-up shaft 92, and the above-described vacuum exhaust means 76.

The gas barrier film 10a having been transported to the take-up chamber 60 is taken up by the take-up shaft 92 in a roll shape so as to be a roll 10aR which is obtained by taking up the gas barrier film 10a, and then provided to the next step.

As shown in FIG. 1B, in the case where the gas barrier film 10b having the organic protective layer 12a as an uppermost layer is manufactured, the process may be performed in which the roll 10aR is loaded onto the rotary shaft 42 of the organic film-forming apparatus 30 similarly to the support roll ZR, the gas barrier film 10a is used as a substrate, the organic protective layer 12a is formed on the silicon nitride layer 14, and the resultant is taken up around the take-up shaft 46 in the same manner as above.

As described above, since the silicon nitride layer 14 is not formed on the organic protective layer 12a that is the uppermost layer, the organic protective layer 12a may contain halogen.

When the gas barrier film having two or more sets of three layers consisting of the organic layer 12, the silicon nitride layer 14, and the mixed layer 16 therebetween as shown in FIG. 1C is manufactured, according to the number of the sets to be formed (the number of the repetitions of the sets of the organic layer 12, the mixed layer 16, and the silicon nitride layer 14), the formation of the organic layer 12 and the silicon nitride layer 14 may be repeatedly in the same manner.

For example, when the gas barrier film 10c having two sets of the organic layer 12, the silicon nitride layer 14, and the mixed layer 16 as shown in FIG. 1C is manufactured, similarly to the example described above, the roll 10aR is loaded onto the rotary shaft 42 of the organic film-forming apparatus 30; the gas barrier film 10a is used as a substrate; the organic layer 12 is formed on the silicon nitride layer 14; and the resultant is taken up around the take-up shaft 46. Thereafter, the roll around the take-up shaft 46 is loaded onto the rotary shaft 64 similarly to the roll ZoR; a second silicon nitride layer 14 is formed on a second organic layer 12 in the same manner as above; and the resultant is taken up around the take-up shaft 92.

When the organic protective layer 12a is formed on the resultant film, the organic protective layer 12a may be formed by loading the roll around the take-up shaft 92 onto the rotary shaft 42 of the organic film-forming apparatus 30, forming the organic protective layer 12a as the uppermost layer on the silicon nitride layer 14 in the same manner as above, and taking up the resultant around the take-up shaft 46.

The functional film manufacturing method and the functional film according to the present invention have been described in detail, but the present invention is not limited to the above examples. Needles to say, the present invention may be improved or modified in various ways, within a range that does not depart from the gist of the present invention.

### EXAMPLES

Hereinafter, the present invention will be described in more detail based on specific examples of the present invention.

### Example 1

### Inventive Example 1

As a functional film, the gas barrier film 10a having the organic layer 12 and the silicon nitride layer 14 on the surface of the support Z as shown in FIG. 1A was prepared.

As the support Z, a long polyethylene terephthalate (PET) film having a width of 1,000 mm and a thickness of 100 μm was used.

An organic compound and a surfactant were put into an organic solvent and mixed, thereby preparing the coating material that is to be the organic layer 12.

As the organic compound, TMPTA (manufactured by Daicel-Cytec Company Ltd.) was used. As the organic solvent, MEK was used.

As the surfactant, a silicon-based surfactant (manufactured by BYK Japan KK, BYK378) was used. The surfactant was added in an amount of 1% by weight in terms of the concentration when the organic solvent is excluded.

Moreover, to the coating material, a photopolymerization initiator (manufactured by Ciba Specialty Chemicals, Inc., Irg184) was also added in an amount of 2% by weight in terms of the concentration when the organic solvent is excluded (that is, the amount of the organic compound was 97% by weight in terms of solid content).

The surfactant and the photopolymerization initiator did not contain halogen.

Moreover, the solid content concentration of the coating material was adjusted to 15% by weight.

The support roll ZR obtained by taking up the support Z was loaded onto the rotary shaft 42 of the organic film-forming apparatus 30 shown in FIG. 2A. Thereafter, the surface of the support Z was coated with the prepared coating material by the coating means 36, the coating material coated was dried by the drying means 38, and then, the dried coating material was crosslinked and cured by the light irradiation means 40, thereby obtaining the roll ZoR by taking up the support Z on which the organic layer 12 had been formed.

A die coater was used as the coating means 36, and the coating amount of the coating material was adjusted to 20 cc/m². When coating was performed using the prepared coating material in this amount, the film thickness of the dry film, that is, the film thickness of the organic layer 12 became 2 μm.

Hot air was used as the drying means 38, and a UV irradiation apparatus was used as the light irradiation means 40.

Thereafter, the roll ZoR was loaded onto the inorganic film-forming apparatus 32 shown in FIG. 2B, and on the surface of the support Zo on which the organic layer 12 had been formed, a silicon nitride layer having a film thickness of 50 nm was formed as the silicon nitride layer 14 by CCP-CVD. Subsequently, the gas barrier film 10a on which the silicon nitride layer 14 had been formed was taken up, thereby preparing the roll 10aR.

As film-forming gas, a silane gas (SiH₄), an ammonia gas (NH₃), a nitrogen gas (N₂), and a hydrogen gas (H₂) were used. The silane gas was supplied in an amount of 100 sccm, the ammonia gas was supplied in an amount of 200 sccm, the nitrogen gas was supplied in an amount of 500 sccm, and the hydrogen gas was supplied in an amount of 500 sccm. Moreover, the film was formed under a pressure of 50 Pa.

To the shower electrode 82, 3,000 W of plasma excitation power was supplied from the high-frequency power source 86 at a frequency of 13.5 MHz. Furthermore, the drum 80 made of stainless steel was used, and 500 W of bias power was supplied from the bias supply (not shown in the drawing). During the film formation, the temperature of the drum 80 was adjusted to −20° C.

### Comparative Example 1

The roll obtained by taking up the gas barrier film was prepared in the same manner as in Inventive Example 1, except that the surfactant added to the coating material for forming the organic layer 12 was replaced with a fluorosurfactant (manufactured by BYK Japan KK, BYK340).

### Comparative Example 2

The roll obtained by taking up the gas barrier film was prepared in the same manner as in Inventive Example 1, except that the surfactant added to the coating material for forming the organic layer 12 was replaced with a surfactant containing both halogen and silicon (obtained by mixing a silicon-based surfactant (BYK378) and a fluorosurfactant (BYK340) at a mixing ratio of 1:1; the surfactant was added in an amount of 1% by weight in terms of the concentration the organic solvent is excluded).

The water vapor permeability [g/(m²·day)] of each of the prepared gas barrier films was measured by a calcium corrosion method (method disclosed in JP 2005-283561 A).

The water vapor permeability was evaluated based on the following criteria.

Water vapor permeability of less than 1×10⁻⁴ [g/(m²·day)]: Excellent

Water vapor permeability of equal to or greater than 1×10⁻⁴ [g/(m²·day)] and less than 1×10⁻³ [g/(m²·day)]: Good

Water vapor permeability of equal to or greater than 1×10⁻³ [g/(m²·day)]: Unacceptable

As a result, Inventive Example 1 was evaluated as “Excellent”, and both the Comparative Examples 1 and 2 were evaluated as “Unacceptable”.

The surface of the silicon nitride layer 14 was observed by AFM (at a viewing angle of 10 μm). As a result, in Comparative Examples 1 and 2, many fine pinholes induced by halogen contained in the organic layer were observed in the silicon nitride layer 14. Due to these pinholes, a high degree of gas barrier properties could not be obtained in the Comparative Examples 1 and 2.

In contrast, in Inventive Example 1 in which the organic layer 12 does not contain halogen, the presence of pinholes was not observed in the silicon nitride layer 14, and the water vapor permeability was 8.2×10⁻⁵ [g/(m²·day)]. Therefore, in Inventive Example 1, an extremely high degree of gas barrier properties in which the water vapor permeability was less than 1×10⁻⁴ [g/(m²·day)] was obtained.

After the organic layer 12 was formed, the surface of the organic layer 12 was also observed by AFM. As a result, it was found that in all of Inventive Example 1 and Comparative Examples 1 and 2, concavities of about tens of nm to hundreds of nm were formed at the surface. In all of Inventive Example 1 and Comparative Examples 1 and 2, the organic layer 12 contained a surfactant, and as described above, the surfactant aggregated at these concavities. In Inventive Example 1 in which the organic layer 12 did not contain halogen, the silicon nitride layer 14 was evenly formed even on the concavities. In contrast, in Comparative Examples 1 and 2 in which the organic layer 12 contained halogen, it was found that pinholes were formed in the silicon nitride layer 14 particularly on the concavities.

### Example 2

### Inventive Examples 2 to 6

The roll 10aR obtained by taking up the gas barrier film 10a was prepared in the same manner as in Inventive Example 1, except that the solid content concentration of the coating material was changed such that the thickness of a dry film formed of the coating material, that is, the film thickness of the organic layer 12 was 0.3 μm when the coating material was applied in an amount of 10 cc/m² (Inventive Example 2); the film thickness was 0.5 μm when the coating material was applied in an amount of 10 cc/m² (Inventive Example 3); the film thickness was 1 μm when the coating material was applied in an amount of 10 cc/m² (Inventive Example 4); the film thickness was 3 μm when the coating material was applied in an amount of 10 cc/m² (Inventive Example 5); and the film thickness was 5 μm when the coating material was applied in an amount of 10 cc/m² (Inventive Example 6).

The water vapor permeability of each of the prepared gas barrier films 10a was measured and evaluated in the same manner as in Example 1. The results are as follows.

Inventive Example 2: Good (4.0×10⁻⁴ [g/(m²·day)])

Inventive Example 3: Excellent (9.9×10⁻⁵ [g/(m²·day)])

Inventive Example 4: Excellent (9.1×10⁻⁵ [g/(m²·day)])

Inventive Example 5: Excellent (7.5×10⁻⁵ [g/(m²·day)])

Inventive Example 6: Good (2.3×10⁻⁴ [g/(m²·day)])

In Inventive Example 2, the gas barrier properties deteriorated even though the silicon nitride layer 14 did not have pinholes, probably because the organic layer 12 was so thin that the surface of the organic layer 12 could not be flattened to a sufficient degree and hence a portion where the silicon nitride layer 14 was not formed was generated.

Moreover, in Inventive Example 5, the gas barrier properties deteriorated even though the silicon nitride layer 14 did not have pinholes, probably because the organic layer 12 was too thick and hence cracked and accordingly, a portion where the silicon nitride layer 14 was generated similarly to the foregoing Inventive Example.

However, in this Example, although the gas barrier films were evaluated as “Good”, the water vapor permeability was 4.0×10⁻⁴ [g/(m²·day)] in Inventive Example 2 and 2.3×10⁻⁴ [g/(m²·day)] in Inventive Example 6. This shows that the gas barrier films have gas barrier properties sufficient for general use.

On the other hand, in Inventive Example 3 to Inventive Example 5 in which the organic layer 12 had an appropriate thickness, the entire surface of the support Z was properly covered, the surface of the organic layer 12 could be flattened to a sufficient degree, and the silicon nitride layer 14 not having pinholes could be formed on the entire surface of the organic layer 12. Accordingly, an extremely high degree of gas barrier properties in which the water vapor permeability was less than 1×10⁻⁴ [g/(m²·day)] could be obtained.

### Example 3

### Inventive Examples 7 to 10

The roll 10aR obtained by taking up the gas barrier film 10a was prepared in the same manner as in Inventive Example 1, except that the solid content concentration of the coating material was changed such that the film thickness of a dry film formed of the coating material, that is, the film thickness of the organic layer 12 was 1 μm when the coating material was applied in an amount of 3 cc/m² (Inventive Example 7); the film thickness was 1 μm when the coating material was applied in an amount of 5 cc/m² (Inventive Example 8); the film thickness was 1 μm when the coating material was applied in an amount of 20 cc/m² (Inventive Example 9); and the film thickness was 1 μm when the coating material was applied in an amount of 30 cc/m² (Inventive Example 10).

The water vapor permeability of each of the prepared gas barrier films 10a was measure and evaluated in the same manner as in Example 1. The results are as follows.

Inventive Example 7: Good (3.2×10⁻⁴ [g/(m²·day)])

Inventive Example 8: Excellent (9.8×10⁻⁵ [g/(m²·day)])

Inventive Example 9: Excellent (9.1×10⁻⁵ [g/(m²·day)])

Inventive Example 10: Good (1.3×10⁻⁴ [g/(m²·day)])

Inventive Example 4 in which the dry film with a thickness of 1 μm was obtained by application of the coating material in an amount of 10 cc/m² was evaluated as “Excellent” since the water vapor permeability was 9.1×10⁻⁵ [g/(m²·day)], and thus had an extremely high degree of gas barrier properties.

In Inventive Example 7, the gas barrier properties deteriorated even though the silicon nitride layer 14 did not have pinholes, probably because the amount of the coating material used was so small that the entire surface of the support Z could not be covered with the organic layer 12 to a sufficient degree and hence a portion where the silicon nitride layer 14 was not formed was generated.

In Inventive Example 10, the gas barrier properties deteriorated even though the silicon nitride layer 14 did not have pinholes, probably because the amount of the coating material used was too large; this made complete removal of a residual solvent difficult; this resulted in poor curing of the film; etching resistance during the formation of the silicon nitride layer 14 deteriorated; this made the mixed layer 16 thick; and this made the substantial silicon nitride layer 14 thin.

However, in this Example, although the gas barrier films were evaluated as “Good”, the water vapor permeability was 3.2×10⁻⁴ [g/(m²·day)] in Inventive Example 7 and 1.3×10⁻⁴ [g/(m²·day)] in Inventive Example 10. This shows that the gas barrier films have gas barrier properties sufficient for general use.

On the other hand, in Inventive Example 8 and Inventive Example 9 in which the coating material for forming the organic layer 12 was used in an appropriate amount, the entire surface of the support Z was properly covered, the surface of the organic layer 12 could be flattened to a sufficient degree, and the silicon nitride layer 14 not having pinholes could be formed on the entire surface of the organic layer 12. Accordingly, an extremely high degree of gas barrier properties in which the water vapor permeability was less than 1×10⁻⁴ [g/(m²·day)] could be obtained.

The above results clearly show the effect of the present invention.

The present invention can be preferably applied to a functional film such as a gas barrier film used for a solar cell, and an organic EL display, and to manufacture the film.

What is claimed is:

1. A functional film manufacturing method, comprising the steps of:
forming an organic layer not containing halogen on a substrate by using a coating material; and
forming a silicon nitride layer on the organic layer plasma CVD.

2. The functional film manufacturing method according to claim 1, wherein the organic layer is formed of a coating material containing an organic solvent, an organic compound, and a surfactant, and
the coating material contains the surfactant in an amount of 0.01% by weight to 10% by weight in terms of the concentration when the organic solvent is excluded.

3. The functional film manufacturing method according to claim 1, wherein the organic layer is formed to have a thickness of 0.5 μm to 5 μm.

4. The functional film manufacturing method according to claim 1, wherein the coating material is applied in an amount of 5 cc/m² to 50 cc/m² to form the organic layer.

5. The functional film manufacturing method according to claim 1, wherein the substrate is drawn from a substrate roll obtained by taking up the substrate having a long length in a roll shape, the organic layer is formed by coating the substrate with the coating material, drying the coating material and curing an organic compound while the substrate is transported in a longitudinal direction, and the substrate on which the organic layer has been formed is taken up again in a roll shape to obtain a substrate/organic layer roll; and
the substrate on which the organic layer has been formed is drawn from the substrate/organic layer roll, the silicon nitride layer is formed while the substrate is transported in the longitudinal direction, and the substrate on which the silicon nitride layer has been formed is taken up again in a roll shape.

6. The functional film manufacturing method according to claim 1, wherein the organic layer is a layer obtained by crosslinking a (meth)acrylate-based organic compound having three or more functional groups.

7. The functional film manufacturing method according to claim 2, wherein the surfactant is a silicon-based surfactant.

8. A functional film comprising:
one or more sets of an organic layer not containing halogen, a silicon nitride layer formed on the organic layer, and an organic/silicon nitride-mixed layer that is formed between the organic layer and the silicon nitride layer and does not contain halogen.

9. The functional film according to claim 8, wherein the organic layer contains a surfactant in an amount of 0.01% by weight to 10% by weight.

10. The functional film according to claim 8, wherein the organic layer has a thickness of 0.5 μm to 5 μm.

11. The functional film according to claim 8, wherein the organic layer is a layer obtained by crosslinking a (meth)acrylate-based organic compound having three or more functional groups.
